(19) United States
(12) Patent Application Publication
(10) Pub. No.: US 2025/0285974 A1
(43) Pub. Date: Sep. 11, 2025

(54) SELF-ALIGNED BACKSIDE VIA FOR BACKSIDE POWER SCHEME

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Min Gyu Sung, Latham, NY (US)

(21) Appl. No.: 18/598,389

(22) Filed: Mar. 7, 2024

(51) Int. Cl. H01L 23/528; H01L 21/768; H01L 21/8234; H01L 23/535; H01L 27/088; H01L 29/06; H01L 29/08

(52) U.S. Cl. CPC H01L 23/5286; H01L 21/76897; H01L 23/535; H10D 62/118; H10D 62/151; H10D 84/0149; H10D 84/038; H10D 84/83

(57) ABSTRACT

Embodiments disclosed herein include a semiconductor structure. The semiconductor structure may include a source/drain (S/D) contact, a backside power rail (RB); and a self-aligned backside via (BSRV). The BSRV may include dielectric sidewalls and a conductive core. The BSRV may electrically connect the S/D contact to the RB.

### BACKGROUND

The present invention relates generally to the field of semiconductor device manufacturing, and more particularly to connecting a source/drain contact to backside power components.

High-performance transistors benefit from advanced techniques for optimizing source and drain regions on both the frontside and backside of the semiconductor substrate. On the frontside, extension implants middle of line (MOL) epitaxy implantation, activation anneal, and silicide formations extension or halo implants are commonly used. Extension implants create shallow, highly doped regions to mitigate short-channel effects and enhance control of the channel under the gate. Silicide formation reduces contact resistance, improving current flow and transistor speed.

On the backside, options vary based on technology and requirements. Through-silicon vias (TSVs) enable vertical connections to the backside for 3D integrated circuits and efficient heat dissipation. Backside doping can modify substrate properties, and thermal management solutions like heat spreaders or heat sinks help dissipate heat. Designers consider factors like power efficiency, thermal management, and reliability when selecting the most suitable methods for high-performance transistors. Optimizing source and drain regions on the frontside involves techniques like extension implants, middle of line (MOL) Epitaxy implantation, activation anneal and silicide formations extension or halo implants to enhance transistor performance. On the backside, solutions like TSVs, backside doping, and thermal management address specific needs, depending on the technology and application.

### SUMMARY

Aspects of an embodiment of the present invention include a semiconductor structure. The semiconductor structure may include a source/drain (S/D) contact, a backside power rail (RB), and a self-aligned backside via (BSRV). The BSRV may include dielectric sidewalls and a conductive core. The BSRV electrically may connect the S/D contact to the RB.

Aspects of an embodiment of the present invention encompass a method of fabricating a semiconductor structure. The method may include forming a self-aligned backside cut in a space between source/drains and between gates of the semiconductor structure, forming dielectric sidewalls in the self-aligned backside cut, forming a backside via (BSRV) between the dielectric sidewalls, wherein the BSRV contacts a source/drain contact, and forming a backside power rail connected to the BSRV.

Aspects of an embodiment of the present invention include a semiconductor structure. The semiconductor structure may include a semiconductor structure a pair of source/drains (S/Ds), a pair of gate channels adjacent to the pair of S/Ds, and a self-aligned backside via (BSRV) between the pair of source/drains and between the pair of gate channels. The BSRV may include dielectric sidewalls and a conductive core. The BSRV may electrically connect a S/D contact to a backside power rail (RB).

### BRIEF DESCRIPTION OF THE DRAWINGS

FIG. 1 depicts a schematic top view of a semiconductor structure at a stage of fabrication, in accordance with one embodiment of the present invention.

FIGS. 2A and 2B depict cross-sectional side views of the semiconductor structure of FIG. 1, with like reference numerals referring to like features at a fabrication stage of the processing method, in accordance with one embodiment of the present invention.

FIGS. 3A and 3B depict cross-sectional side views of the semiconductor structure of FIG. 1, with like reference numerals referring to like features at a fabrication stage of the processing method, in accordance with one embodiment of the present invention.

FIGS. 4A and 4B depict cross-sectional side views of the semiconductor structure of FIG. 1, with like reference numerals referring to like features at a fabrication stage of the processing method, in accordance with one embodiment of the present invention.

FIGS. 5A and 5B depict cross-sectional side views of the semiconductor structure of FIG. 1, with like reference numerals referring to like features at a fabrication stage of the processing method, in accordance with one embodiment of the present invention.

FIGS. 6A and 6B depict cross-sectional side views of the semiconductor structure of FIG. 1, with like reference numerals referring to like features at a fabrication stage of the processing method, in accordance with one embodiment of the present invention.

FIGS. 7A and 7B depict cross-sectional side views of the semiconductor structure of FIG. 1, with like reference numerals referring to like features at a fabrication stage of the processing method, in accordance with one embodiment of the present invention.

FIGS. 8A and 8B depict cross-sectional side views of the semiconductor structure of FIG. 1, with like reference numerals referring to like features at a fabrication stage of the processing method, in accordance with one embodiment of the present invention.

FIGS. 9A and 9B depict cross-sectional side views of the semiconductor structure of FIG. 1, with like reference numerals referring to like features at a fabrication stage of the processing method, in accordance with one embodiment of the present invention.

FIGS. 10A and 10B depict cross-sectional side views of the semiconductor structure of FIG. 1, with like reference numerals referring to like features at a fabrication stage of the processing method, in accordance with one embodiment of the present invention.

FIGS. 11A and 11B depict cross-sectional side views of the semiconductor structure of FIG. 1, with like reference numerals referring to like features at a fabrication stage of the processing method, in accordance with one embodiment of the present invention.

FIGS. 12A and 12B depict cross-sectional side views of the semiconductor structure of FIG. 1, with like reference numerals referring to like features at a fabrication stage of the processing method, in accordance with one embodiment of the present invention.

FIGS. 13A and 13B depict cross-sectional side views of the semiconductor structure of FIG. 1, with like reference numerals referring to like features at a fabrication stage of the processing method, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly adjacent,” “directly on,” or “directly over” another element, there are no intervening elements present. It will also be understood that when an element is referred to as being “beneath” or “under” another element, it can be directly below or under the other element, or intervening elements may be present. Additionally, when an element is referred to as being “directly below” or “directly above” another element, intervening elements may be present, but the elements overlap at least partially relative to a vertical axis perpendicular to a major surface. With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface and “horizontal” means substantially parallel to the major surface. Typically, the major surface is along a plane of a monocrystalline silicon layer on which transistor devices are fabricated. Each reference number may refer to an item individually or collectively as a group. For example, a contact 202 may refer to a single contact 202 or multiple contacts 202.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. In some embodiments, epitaxial growth and/or deposition processes can be selective to forming on semiconductor surfaces, and may or may not deposit material on other exposed surfaces, such as silicon dioxide or silicon nitride surfaces.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made, without departing from the spirit and scope defined by the claims. The description of the embodiments is not limiting. In particular, elements of the embodiments described hereinafter may be combined with elements of different embodiments.

In some embodiments, etching mask layer(s) may be provided, and the layers that are not protected thereby are removed. For example, as is understood in the art, a mask layer, sometimes referred to as a photomask, may be provided by forming a layer of photoresist material on another layer, exposing the photoresist material to a pattern of light, and developing the exposed photoresist material. An etching process, such as a reactive ion etch (RIE), may be used to form patterns (e.g., openings) by removing portions of another layer. After etching, the mask layer may be removed using a conventional plasma ashing or stripping process. Accordingly, the pattern of the mask layer facilitates the removal of another layer, such as an amorphous SiO2 layer and/or a conductive oxide diffusion barrier, for example, in areas where the mask layer has not been deposited.

For the sake of brevity, conventional techniques related to semiconductor structure and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor structures and semiconductor-based ICs are well known and so, in the interest of brevity, many conventional steps will only be mentioned briefly herein or will be omitted entirely without providing the well-known process details.

Improvements in the design of integrated circuits (IC) have enabled feature sizes for transistors in a device layer to enter into deep submicron and nanometer regime. Embodiments herein recognize benefits from separating the power delivery components from the signal wires. A backside power delivery network (BSPDN) and/or backside power rails (BPR), for example, can greatly improve the routability for field-effect transistor (FET). Improving routability means the design of the IC provides easier connection between source/drains (S/Ds), gates, etc. and the other components of the IC. The embodiments herein also recognize that the decrease in feature size can mean that the electrical connection between the S/Ds and the other components decreases performance due to the small contact area connecting the S/Ds to the metallized contacts.

Embodiments disclosed herein, therefore, include semiconductor structures with a BSRV insulated from source/drains and gates through the use of dielectric sidewalls. Embodiments may include a source/drain (S/D) contact providing the technical benefit of electrically connecting S/Ds to other electrical components within the semiconductor structure, and in turn connect to external signal readers and signal generators. Certain embodiments also include a backside power rail (RB) that is part of a backside power delivery network (BSPDN) conveying power signals on a backside of the semiconductor structure. Certain embodiments also include a self-aligned backside via (BSRV) with dielectric sidewalls and a conductive core.

As mentioned, the dielectric sidewalls insulate the conductive core of the BSRV from adjacent components like gates and S/Ds. The BSRV electrically connects the S/D contact to the RB.

The BSRV, in certain embodiments of the semiconductor structures described herein, includes a length that is longer than a length of the S/D contact to provide the technical benefit of increasing the surface area between the BSRV and the RB, which in turn decreases the resistance between the BSRV and the RB and increases overall efficiency of the semiconductor structure. Further embodiments of the semiconductor structure may include a first gate and a second gate. With the BSRV passing between the first gate and the second gate to provide the technical benefit of increased cell density. In other words, embodiments of the BSRV may be fabricated with very tight spacing between the gates of the semiconductor structure. Certain embodiments of the semiconductor structure may include a dielectric cap between the first gate and the RB that is a result of the fabrication process to self-align the BSRV. The dielectric cap provides the technical benefit of protecting the first gate during the etching of the cut for the BSRV. Certain embodiments may include a self-aligned backside gate-and-S/D-dielectric cut on a side of the first gate opposite the BSRV to provide the technical benefit of isolating the gates and S/Ds along one lateral direction. In certain embodiments, the self-aligned backside gate and S/D dielectric cut may dielectric sidewalls and a dielectric core. This is similar in structure to the dielectric sidewalls and conductive core of the BSRV, and the backside gate-and-S/D-dielectric cuts may be made at the same time as the BSRV cut, which increases efficiency of the fabrication process. In certain embodiments the BSRV may be tapered in a direction away from the RB, indicating a direction (i.e., from the backside rather than the frontside) of etch during formation. A backside etch direction provides the technical benefit of backside contact with the frontside S/Ds. The dielectric sidewalls may extend in some embodiments laterally beyond the conductive core to provide the technical benefit of consistent fabrication without the need to selectively place the dielectric sidewalls. Rather, the dielectric sidewalls can be formed along the entire length of a BSRV cut, but then the BSRV is subsequently formed in a more accurate location. In certain embodiments, the dielectric sidewalls may be formed in the BSRV cut such that it overlaps the S/D contact and in the final device the dielectric sidewalls are located between the BSRV and the S/D contact. The dielectric sidewalls being between the BSRV and the S/D contact is a sign of the dielectric sidewalls being fabricated as a blanket layer in the BSRV cut, which provides the technical benefit straightforward fabrication process that still isolate the BSRV while still enabling robust electrical connection with the S/D contact.

Certain embodiments of the present invention include a method of fabricating a semiconductor structure. The methods may include forming a self-aligned backside cut in a space between source/drains and between gates of the semiconductor structure, forming dielectric sidewalls in the self-aligned backside cut, and forming a backside via (BSRV) between the dielectric sidewalls. The method may also include forming a backside power rail connected to the BSRV. The BSRV may contact a source/drain contact to enable an electrical connection between a S/D and a backside power delivery network. In certain embodiments, forming the self-aligned backside cut may include etching between gates to isolate and protect the gates. In certain embodiments, the dielectric sidewalls are formed between the gates to provide structure for the fabrication of further components of the semiconductor structure. In certain embodiments, the self-aligned backside cut is self-aligned by dielectric caps formed over the source/drains. The dielectric cap provides the technical benefit of protecting the first gate during the etching of the cut for the BSRV.

Certain embodiments of the present invention may include a semiconductor structure having a pair of source/drains (S/Ds), a pair of gate channels adjacent to the pair of S/Ds, and a self-aligned backside via (BSRV) between the pair of source/drains and between the pair of gate channels. The pairs may be adjacent structures along any row or column of the semiconductor structure. The BSRV may include dielectric sidewalls and a conductive core. As mentioned, the dielectric sidewalls insulate the conductive core of the BSRV from adjacent components like gates and S/Ds. The BSRV electrically connects the S/D contact to the RB. The BSRV electrically connects a S/D contact to a backside power rail (RB).

The present invention and an example fabrication process will now be described in detail with reference to the Figures.

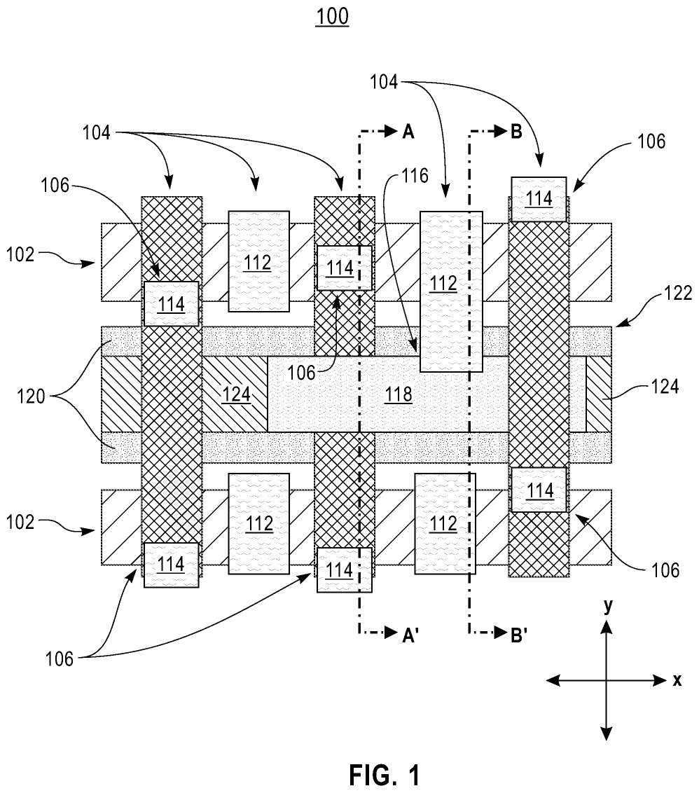

FIG. 1 depicts a schematic top view of a semiconductor structure 100 at a stage of fabrication, in accordance with one embodiment of the present invention. The semiconductor structure 100 is organized as rows 102 and columns 104 of field-effect transistor (FET) devices 106 fabricated in a front-end-of-line (FEOL) layer of the semiconductor device 100. The columns 104 include gates that control channels between source/drains (S/Ds) of the FET devices 106. The semiconductor structure 100 also includes gate contacts 114 and S/D contacts 112 that electrically connect the gates and S/Ds to a back-end-of-line (BEOL) interconnect network on a front side of the semiconductor structure 100. The semiconductor structure 100 also includes a self-aligned backside via (BSRV) 116 that connects a S/D to a backside power delivery network (BSPDN) on a back side of the semiconductor structure 100. The BSRV 116 includes a conductive core 118 and dielectric sidewalls 120 in a backside cut region 122 between the rows 102 of S/Ds. The backside cut region 122 may also be filled at lateral ends of the conductive core 118 by dielectric fill material 124. The conductive core 118 extends laterally within the backside cut region 122 to increase a connection area between the conductive core 118 and abackside power rail as illustrated below. The BSRV 116 (i.e., the conductive core 118 portion) may have a length that is three times a width within the backside cut region 122, such that the BSRV 116 passes between two of the gates (locations shown in FIG. 1 as gate contacts 114 on either side of the conductive core 118). The fabrication and functionality of the BSRV 116 will be shown in greater detail in the following figures and description.

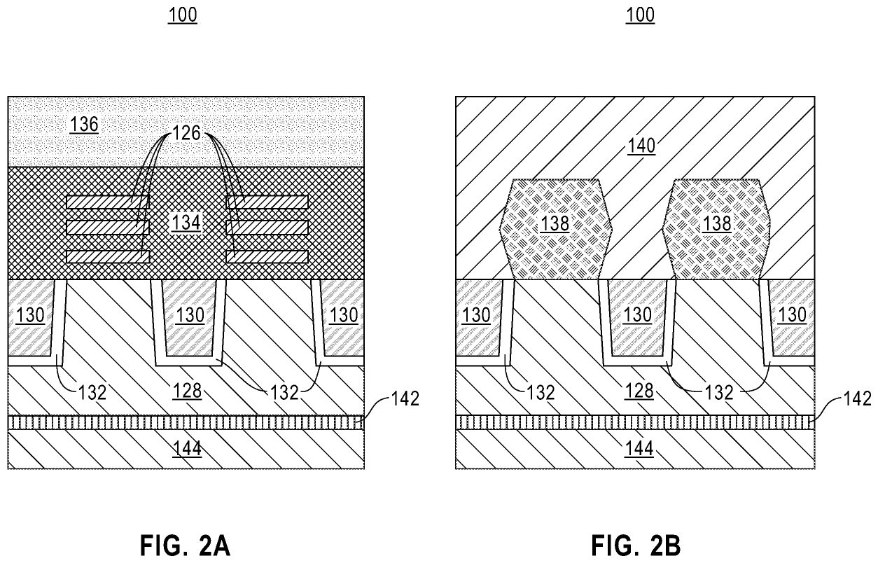

FIGS. 2A and 2B depict cross-sectional side views of the semiconductor structure 100 of FIG. 1, with like reference numerals referring to like features at a fabrication stage of the processing method, in accordance with one embodiment of the present invention. FIG. 2A is a cross-sectional side view along line A-A′ and FIG. 2B is a cross-sectional side view along line B-B′. The semiconductor structure 100 includes nanosheets 126 that are formed as blanket layers on a substrate 128. The nanosheets 126 may be composed of a semiconductor material, such as silicon (Si), and may be formed by an epitaxial growth process followed by cleanly removing sacrificial layers and replacing them with a high-K metal gate (HKMG) 134. As used herein, the term “cleanly” in reference to a material removal process (e.g., etching) denotes that, with an appropriate etchant choice, the material removal rate (i.e., etch rate) for the targeted material is greater than the removal rate for at least another material exposed to the material removal process.

The nanosheets 128 may be isolated along a first lateral direction (i.e., x-axis FIG. 1) by shallow trench isolation (STI) 130 lined with an STI liner 132 between the STI 130 and the substrate 128. The STI 130, STI liner 132 and substrate 128 may be made of dielectric materials (e.g., silicon nitride (SiN), silicon boron carbon nitride (SiBCN), silicon oxygen carbon nitride, (SiOCN), silicon oxygen carbide (SiOC)) that have different etch selectivity from one another.

The HKMG 134 may be covered by a sacrificial cap 136 for protection. The nanosheets 126 are also etched along a second lateral direction (i.e., y-axis FIG. 1) such that at each end of the channels are open for the epitaxial growth of source/drains (S/Ds) 138 that are subsequently surrounded by protective interlayer dielectric (ILD) 140.

The semiconductor structure 100 may also include an etch stop layer 126 and a structural substrate 128 that are not necessarily drawn to scale. Function and utility of the etch stop layer 126 and structural substrate 128 will be explained in detail below.

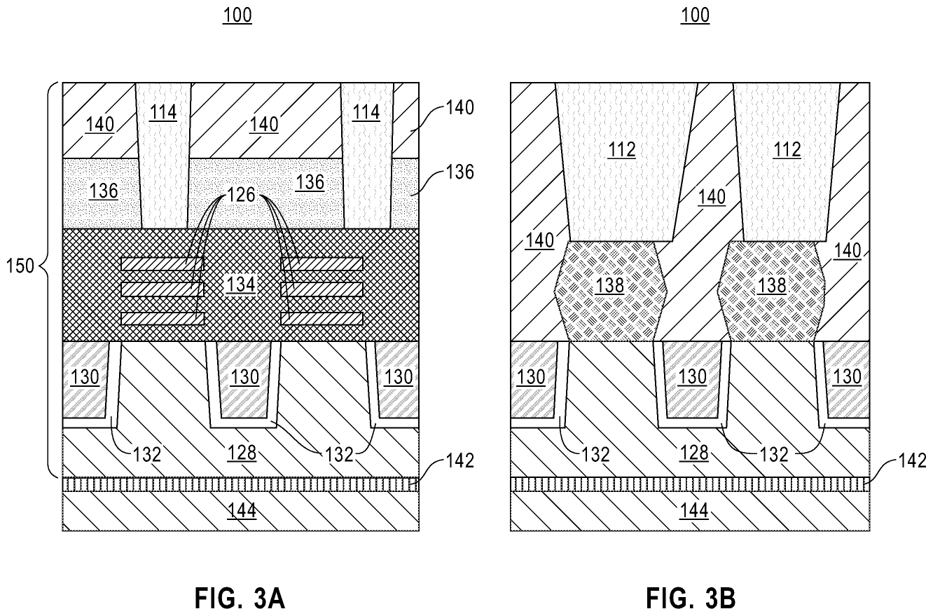

FIGS. 3A and 3B depict cross-sectional side views of the semiconductor structure 100 of FIG. 1 at a subsequent fabrication stage of the processing method, in accordance with one embodiment of the present invention. The cross-sectional views of FIGS. 3A and 3B are along the same lines (A-A′ and B-B′) as FIGS. 2A and 2B. The rest of the figures in this description will also be along the same lines, and will not be individually called out below. The semiconductor structure 100 includes an extra addition of ILD 140, and the S/D contacts 112 and the gate contacts 114. The S/D contacts 112 and the gate contacts 114 may be formed in one or multiple stages of lithographically patterning a hardmask, etching holes for the contacts, and then filling the holes with a conductive fill material (e.g., metal). For example, the holes for the S/D contacts 112 may be formed in one step using a first patterning of a hardmask (e.g., organic planarization layer (OPL)) followed by a second patterning of a second hardmask to form the holes for the gate contacts 114. Both types of holes may then be filled with conductive material. Additional steps may also be used in the method. For example, the BSRV 116 portion of one of the S/D contacts 112 may be formed at the same time as the S/D contacts 112, or as an additional patterning, etching, and filling process.

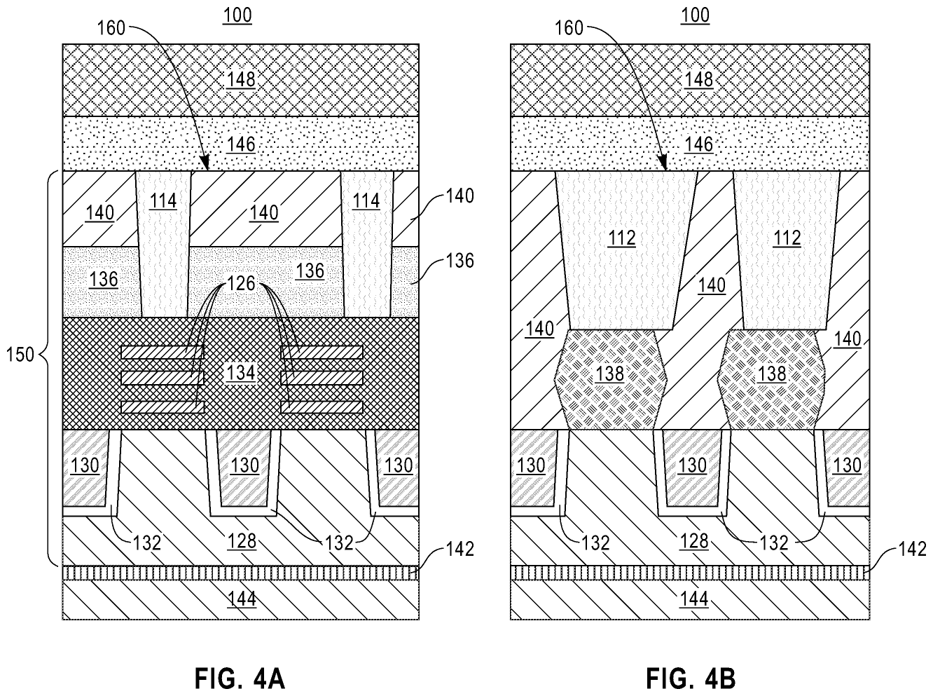

FIGS. 4A and 4B depict cross-sectional side views of the semiconductor structure 100 of FIG. 1 at a subsequent fabrication stage of the processing method, in accordance with one embodiment of the present invention. The semiconductor structure 100 includes a back-end-of-line (BEOL) 146 and a carrier wafer 148 that have been bonded to the frontside of a front-end-of-line (FEOL) 150 that includes the components described above. The BEOL 146 connects the FEOL 150 (and included FETs 106) to external power and communication sources, and includes many (e.g., dozens) of layers of wires, vias, and connects. The BEOL146 layers are formed by first depositing insulating materials (typically silicon dioxide or low-k dielectrics) on top of the FEOL 150, then using lithography and etching techniques to define patterns for metal interconnects and vias in this insulating layer. Subsequently, metal layers (commonly aluminum or copper) are deposited, and further lithography and etching steps are employed to shape these layers into interconnects and vias. This process is repeated to build multiple layers of insulating materials, metal interconnects, and vias as needed for the specific semiconductor technology and device, ultimately finishing with a top insulating layer and the carrier wafer 148 that serves to protect the metal interconnects and complete the BEOL 146. The carrier wafer 148 is sturdy enough that the wafer of the semiconductor structure 100 may be flipped over and supported by the carrier wafer 148 during fabrication steps that take place on the backside of the FEOL 150.

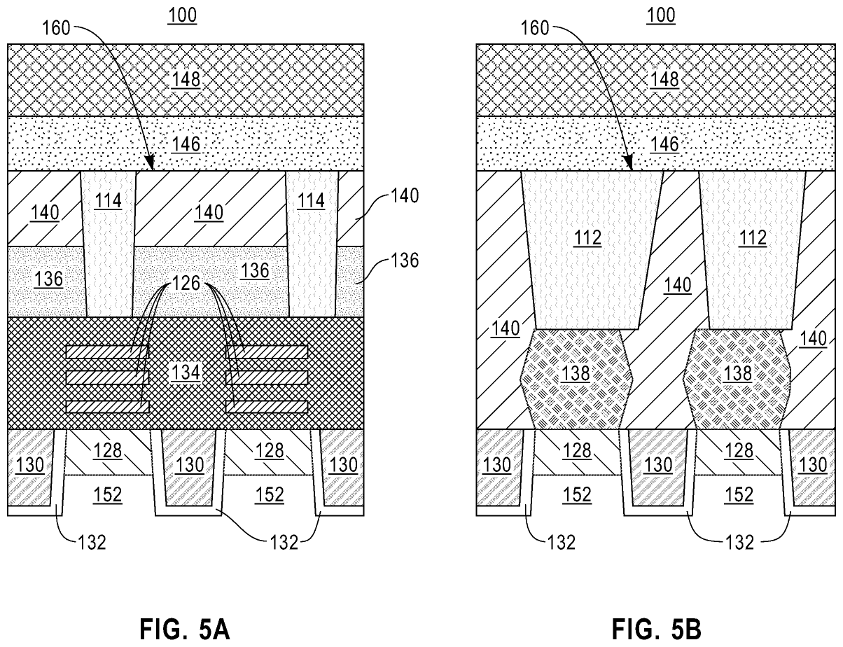

FIGS. 5A and 5B depict cross-sectional side views of the semiconductor structure 100 of FIG. 1 at a subsequent fabrication stage of the processing method, in accordance with one embodiment of the present invention. The semiconductor structure 100 undergoes a process to remove the backside of the FEOL 150, including the structural substrate 144, the etch stop layer 142, and portions of the substrate 128 to leave divots 152 above the remaining substrate 128 between the STI 130 and STI liners 132. The backside of the FEOL 150 may be removed in steps, with the structural substrate 144 being removed first through a rough etch process that is done with simultaneous monitoring (e.g., measuring an electrical signal) of the etch stop layer 142. When the rough etch process contacts the etch stop layer 142, the rough etch stops. This saves the FEOL 150 from damage since the rough etch process used to remove the structural substrate 144 could potentially damage the components in the FEOL 150. The etch stop layer 142 and the substrate 128 are removed with selective etch processes that are finer than the rough etch process. These finer processes do not affect the STI liner 132.

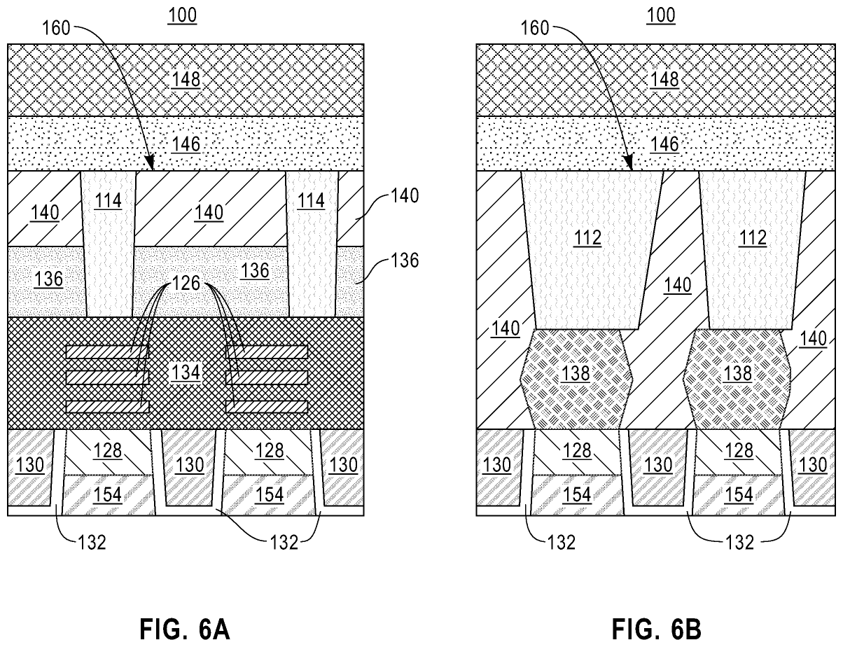

FIGS. 6A and 6B depict cross-sectional side views of the semiconductor structure 100 of FIG. 1 at a subsequent fabrication stage of the processing method, in accordance with one embodiment of the present invention. The semiconductor structure 100 includes dielectric caps 154 that has been filled into the divots 152. The dielectric caps 154 may include dielectric materials such as silicon carbide or others that are etch selective to the STI liner 132 and the STI 130. Following the filling of the divots 152 and formation of the dielectric caps 154, the semiconductor structure 100 may be chemically-mechanically polished (CMP) so that the surface of the wafer may be smooth.

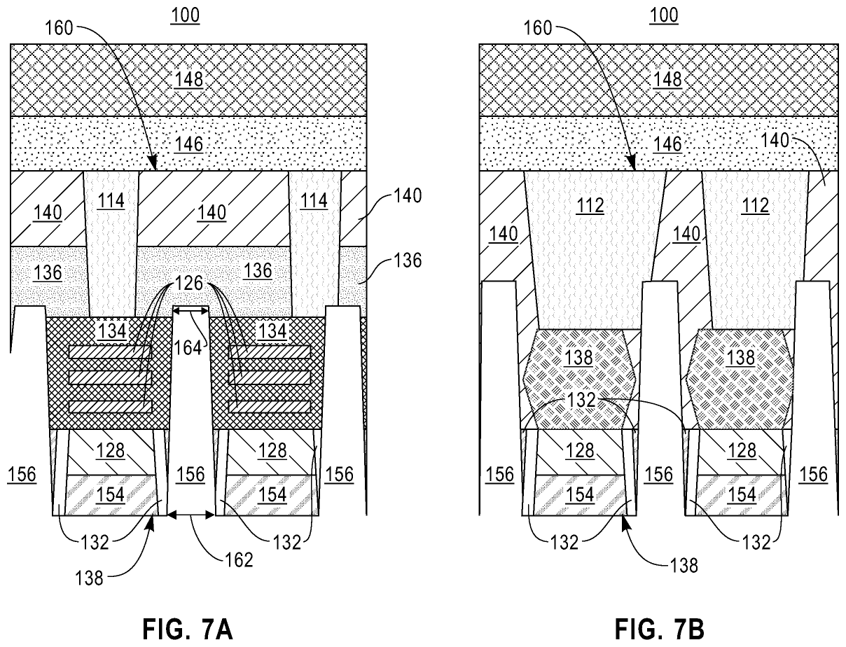

FIGS. 7A and 7B depict cross-sectional side views of the semiconductor structure 100 of FIG. 1 at a subsequent fabrication stage of the processing method, in accordance with one embodiment of the present invention. The semiconductor structure 100 includes self-aligned backside cuts 156 that have been cut between a pair of the S/Ds 138 and between an adjacent pair of the nanosheet channels 126. The self-aligned backside cuts 156 are also etched on the outside of the pair of the S/Ds 138 and the outside of the pair of the nanosheet channels 126. Being “self-aligned” means that an etch cut, and the resulting filled in material, is resultant from an etch process that is selective to specific areas based on components within the semiconductor structure 100 rather than any lithographically patterned hardmask. In the case of the self-aligned backside cuts 156, the dielectric caps 154 are not affected by the etch process used, and the STI liner 132 is affected. Thus, regardless of any lithographic patterning, the self-aligned backside cuts 156 will be etched between the dielectric caps 154. The self-aligned backside cuts 156 etch through the HKMG 134, the sacrificial cap 136, the gate contacts 114, and the S/D contacts 112. The self-aligned backside cuts 156 then taper from a backside 158 toward a frontside 160. That is, a backside critical dimension 162 is larger than a more frontside critical dimension 164.

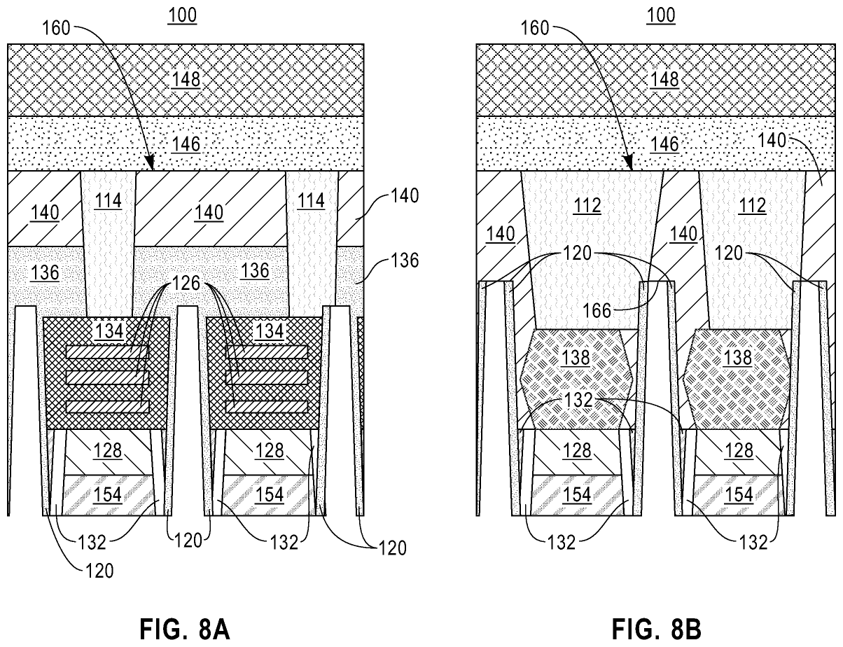

FIGS. 8A and 8B depict cross-sectional side views of the semiconductor structure 100 of FIG. 1 at a subsequent fabrication stage of the processing method, in accordance with one embodiment of the present invention. The semiconductor structure 100 includes dielectric sidewalls 120 deposited on the inside sidewalls of the self-aligned backside cuts 156. The dielectric sidewalls 120 may be fabricated from known dielectric liner materials such as silicon nitride. The dielectric sidewalls 120 may be deposited as a blanket layer using chemical vapor deposition (CVD) and then a breakthrough process is used whereby the S/D contact 112 is exposed at a breakthrough point 166. The breakthrough process may include a directional etch process that etches the horizontal areas of the dielectric sidewalls 120 (already etched in FIGS. 8A and 8B) faster than the more vertical areas of the dielectric sidewalls 120, which is then stopped when the S/D contact 112 is exposed and before the dielectric sidewalls 120 are etched from the sidewalls of the self-aligned backside cuts 156.

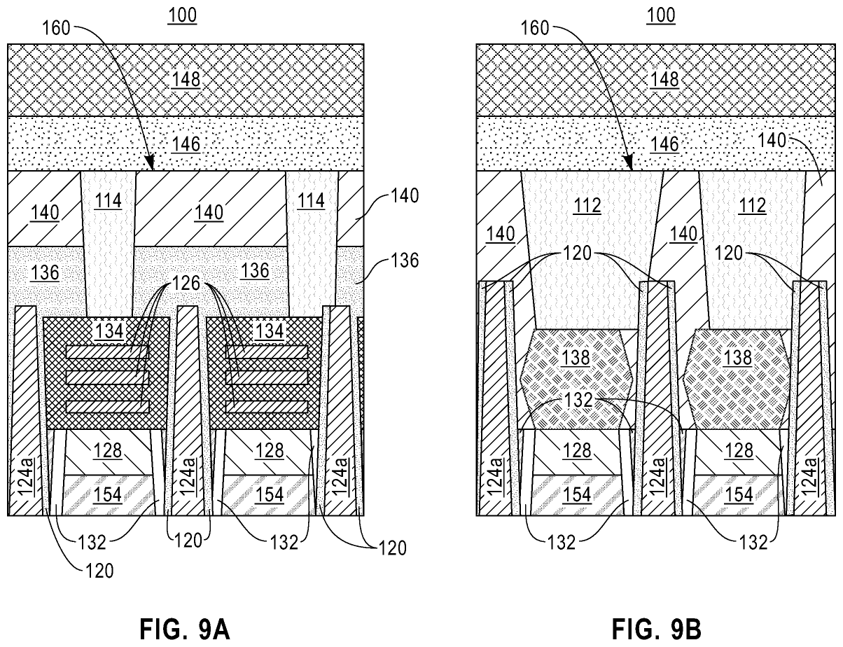

FIGS. 9A and 9B depict cross-sectional side views of the semiconductor structure 100 of FIG. 1 at a subsequent fabrication stage of the processing method, in accordance with one embodiment of the present invention. The semiconductor structure 100 includes the dielectric fill material 124 filling in the self-aligned backside cuts 156 in the space between the dielectric sidewalls 120. The dielectric fill material 124 may be deposited on the backside 158 of the semiconductor structure 100 and then a CMP process may smooth the backside 158 again.

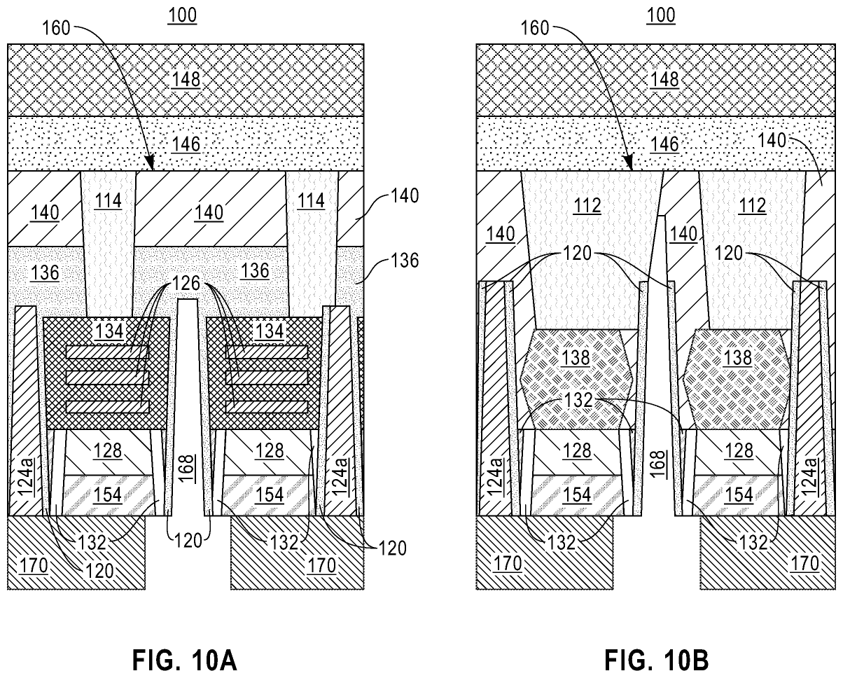

FIGS. 10A and 10B depict cross-sectional side views of the semiconductor structure 100 of FIG. 1 at a subsequent fabrication stage of the processing method, in accordance with one embodiment of the present invention. The semiconductor structure 100 includes a BSRV cut 168 etched through the dielectric fill material 124, but only in a space that is not masked by an organic planarization layer (OPL) hardmask 170. The etch process used to etch away the dielectric fill material 124 may be, for example, an anisotropic plasma etch that is selective to silicon nitride and/or silicon carbide and does affect the dielectric sidewalls 120 or the dielectric caps 154, and thus the backside critical dimension 162 does not grow bigger than the dielectric sidewalls 120. In certain embodiments the etch process may etch into the ILD 140. The etching of the ILD 140 further exposes the S/D contact 112 at an area beyond the dielectric sidewalls 120. The remaining portions of the dielectric fill material 124 form self-aligned backside gate-and-S/D-dielectric cuts 124a on the outsides of the pair of S/Ds 138 and the outsides of the pair of gate channels 126. That is, the self-aligned backside gate-and-S/D-dielectric cuts 124a formed on sides of the S/Ds 138 and gate channels 126 that are opposite the BSRV 116.

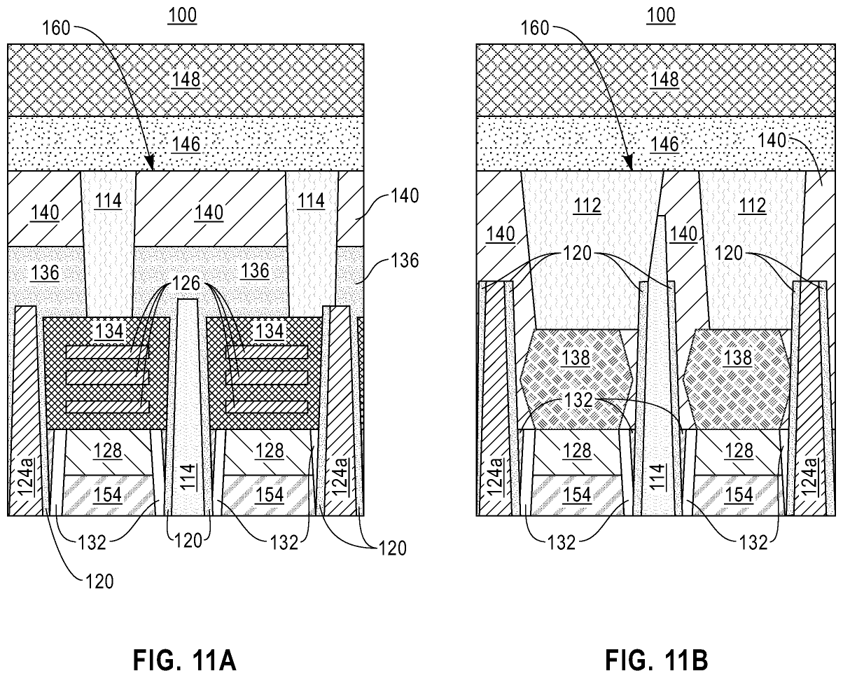

FIGS. 11A and 11B depict cross-sectional side views of the semiconductor structure 100 of FIG. 1 at a subsequent fabrication stage of the processing method, in accordance with one embodiment of the present invention. The semiconductor structure 100 includes the conductive core 118 of the BSRV 116, due to the metallization of the BSRV cut 168. The conductive core 118 contacts the S/D contact 112 at a distal end (i.e., toward the frontside 160) in the S/D area pictured in FIG. 11B, and is bounded by the dielectric sidewalls 120 along the left and right sides as shown in FIG. 11B. The BSRV 116 does not electrically contact any conductive material in the gate region shown in FIG. 11A, as the only bordering components are the dielectric sidewalls 120, and the sacrificial cap 136 at the distal end. The BSRV 116 does not extend fully along the length of the self-aligned backside cuts 156: as shown back in FIG. 1, the BSRV 116 is confined on lateral ends by dielectric fill material 124 that is not etched (e.g., is covered by the OPL 170) during the etch process that forms the BSRV cut 168. In other words, the dielectric sidewalls 120 extend laterally beyond the conductive core 118 of the BSRV 116. The resulting structure of the BSRV 116 strongly connects to the S/D contact 112 to enable efficient signal transmission with protection against shorting to the S/Ds 138 or the nanosheets 126 of the gates. The formation of the dielectric sidewalls 120 over the S/D contact 112 also means that a portion of one of the dielectric sidewalls 120 is located between BSRV 116 and the S/D contact 112.

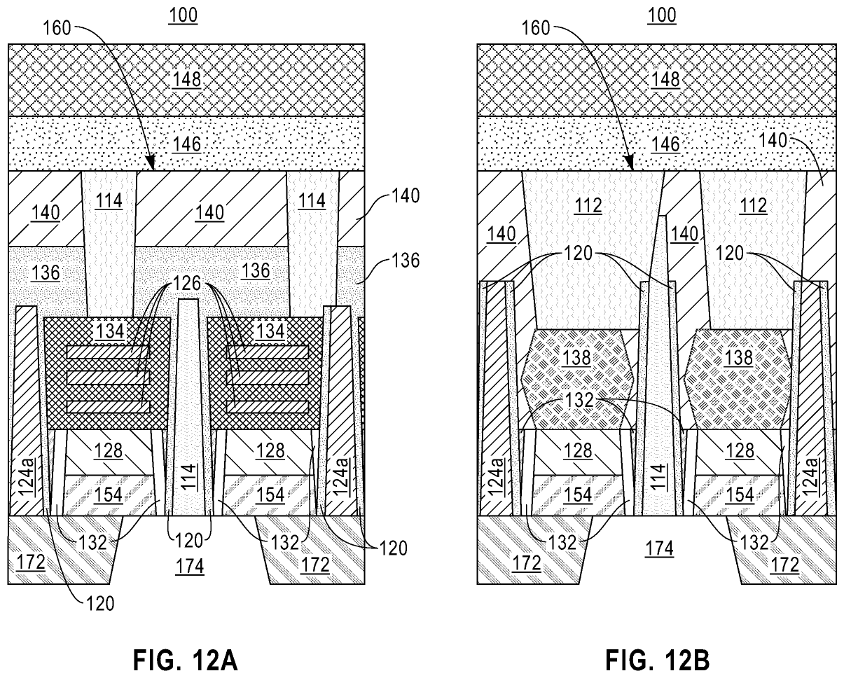

FIGS. 12A and 12B depict cross-sectional side views of the semiconductor structure 100 of FIG. 1 at a subsequent fabrication stage of the processing method, in accordance with one embodiment of the present invention. The semiconductor structure 100 includes a backside ILD (BILD) 172 and a first metal layer cut 174 etched into the BILD 172. The BILD 172 is formed over the backside 158 of the semiconductor structure 100 as a blanket layer, and then lithographically patterned and etched to form the first metal layer cut 174. The backside ILD 178 may include insulating materials used to electrically isolate different layers of interconnects and transistors. Common materials include silicon dioxide (SiO₂), low-k dielectrics with lower dielectric constants, organosilicate glass (OSG), porous low-k dielectrics, and hybrid dielectrics. These materials serve to reduce signal delay, capacitance, and improve the overall performance of the semiconductor structure 100, with the choice depending on the specific technology and manufacturing requirements.

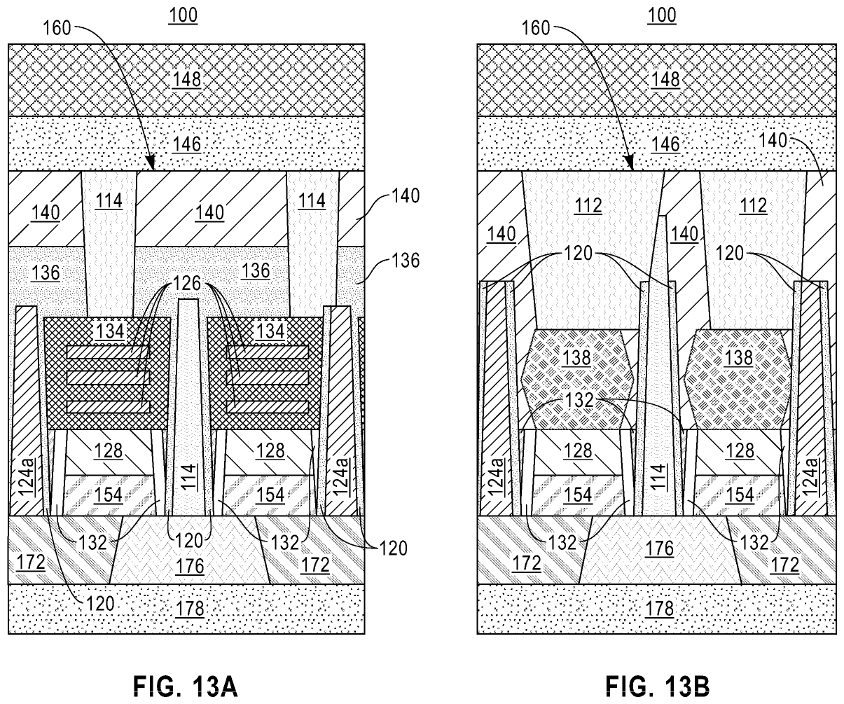

FIGS. 13A and 13B depict cross-sectional side views of the semiconductor structure 100 of FIG. 1 at a subsequent fabrication stage of the processing method, in accordance with one embodiment of the present invention. The semiconductor structure 100 includes a backside power rail 176 and a backside power delivery network (BSPDN) 178. The BSPDN 178 is not drawn to scale, and may contain many (e.g., dozens) of metal layers providing power to many devices in the FEOL 150. The connection between the backside power rail 176 and the BSRV 116 can cause resistance in the circuit due to differences in the material (especially in cases where one material can oxidize to form a barrier to signal conduction), and a larger area of contact between the backside power rail 176 and the BSRV 116 can reduce this resistance. The BSRV 116 in this embodiment, therefore, includes an elongated self-aligned BSRV 116 that not only connects to the backside power rail 176 at between the S/Ds 138, but includes a portion of the BSRV 116 that connects to the backside power rail 176 between the nanosheets 126 of the gates. The dielectric sidewalls 120 prevent this portion of the BSRV 116 from shorting to the nanosheets 126, and enable the self-alignment of the BSRV 116 during fabrication.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a source/drain (S/D) contact;
a backside power rail (RB); and
a self-aligned backside via (BSRV), comprising:
dielectric sidewalls; and
a conductive core, wherein the BSRV electrically connects the S/D contact to the RB.

2. The semiconductor structure of claim 1, wherein the BSRV comprises a length that is longer than a length of the S/D contact.

3. The semiconductor structure of claim 1, further comprising:
a first gate; and
a second gate, wherein the BSRV passes between the first gate and the second gate.

4. The semiconductor structure of claim 3, further comprising:
a dielectric cap between the first gate and the RB.

5. The semiconductor structure of claim 3, further comprising a self-aligned backside gate-and-S/D-dielectric cut on a side of the first gate opposite the BSRV.

6. The semiconductor structure of claim 5, wherein the self-aligned backside gate and S/D dielectric cut comprises:
dielectric sidewalls; and
a dielectric core.

7. The semiconductor structure of claim 1, wherein the BSRV is tapered in a direction away from the RB.

8. The semiconductor structure of claim 1, wherein the dielectric sidewalls extend laterally beyond the conductive core.

9. The semiconductor structure of claim 1, wherein a portion of one of the dielectric sidewalls is located between the BSRV and the S/D contact.

10. A method of fabricating a semiconductor structure, comprising:
forming a self-aligned backside cut in a space between source/drains and between gates of the semiconductor structure;
forming dielectric sidewalls in the self-aligned backside cut;
forming a backside via (BSRV) between the dielectric sidewalls, wherein the BSRV contacts a source/drain contact; and
forming a backside power rail connected to the BSRV.

11. The method of claim 10, wherein forming the self-aligned backside cut comprises etching between gates.

12. The method of claim 11, wherein the dielectric sidewalls are formed between the gates.

13. The method of claim 10, wherein the self-aligned backside cut is self-aligned by dielectric caps formed over the source/drains.

14. A semiconductor structure, comprising:
a pair of source/drains (S/Ds);
a pair of gate channels adjacent to the pair of S/Ds; and
a self-aligned backside via (BSRV) between the pair of source/drains and between the pair of gate channels, comprising:
dielectric sidewalls; and
a conductive core, wherein the BSRV electrically connects a S/D contact to a backside power rail (RB).

15. The semiconductor structure of claim 14, further comprising a backside power rail electrically connected to the BSRV.

16. The semiconductor structure of claim 15, further comprising dielectric caps between i) the BSRV and the pair of S/Ds and ii) the BSRV and the pair of gate channels.

17. The semiconductor structure of claim 14, further comprising a self-aligned backside gate-and-S/D-dielectric cut on a side of one of the pair of S/Ds, wherein the side is opposite the BSRV.

18. The semiconductor structure of claim 17, wherein the self-aligned backside gate and S/D dielectric cut comprises:
dielectric sidewalls; and
a dielectric core.

19. The semiconductor structure of claim 14, wherein the BSRV is tapered in a direction away from the RB.

20. The semiconductor structure of claim 15, wherein the dielectric sidewalls extend laterally beyond the conductive core.
